(19) United States
(12) Patent Application Publication
(10) Pub. No.: US 2025/0079255 A1
(43) Pub. Date: Mar. 6, 2025

(54) ELECTRONIC PACKAGE AND HEAT DISSIPATION STRUCTURE THEREOF

(71) Applicant: SILICONWARE PRECISION INDUSTRIES CO., LTD., Taichung City (TW)

(72) Inventors: Wei-Jhen CHEN, Taichung City (TW); Chih-Hsun HSU, Taichung City (TW); Chih-Nan LIN, Taichung City (TW); Yuan-Hung HSU, Taichung City (TW); Don-Son JIANG, Taichung City (TW)

(73) Assignee: SILICONWARE PRECISION INDUSTRIES CO., LTD., Taichung City (TW)

(21) Appl. No.: 18/428,103

(22) Filed: Jan. 31, 2024

(30) Foreign Application Priority Data
Sep. 1, 2023 (TW) 112133339

(51) Int. Cl. H01L 23/367; H01L 23/00

(52) U.S. Cl. CPC H01L 23/3675; H01L 24/16; H01L 24/32; H01L 24/33; H01L 24/73; H01L 2224/16225; H01L 2224/32225; H01L 2224/32245; H01L 2224/33181; H01L 2224/73204; H01L 2224/73253

(57) ABSTRACT

An electronic package and a heat dissipation structure thereof are provided, in which a supporting member of the heat dissipation structure is disposed around an outer periphery of a central area and has grooves at corner areas. In this way, the grooves can avoid stress concentration in the corner areas, and the rest of the supporting member can well connect and fix the heat dissipation structure and a carrying structure, so as to suppress warpage of the entire electronic package and prevent delamination.

### BACKGROUND

### 1. Technical Field

The present disclosure relates to a packaging structure, and more particularly, to an electronic package and its heat dissipation structure that improves reliability.

### 2. Description of Related Art

Flip-Chip Ball Grid Array (FCBGA) semiconductor package is a device that electrically connects the active surface of at least one chip to one of surfaces of a substrate via a plurality of solder bumps, and a plurality of solder balls serving as input/output (I/O) terminals are placed on the other one of the surfaces of the substrate. This packaging structure can greatly reduce the volume, and at the same time eliminate the conventional wire design, and can reduce impedance and improve electrical properties to avoid signal degradation during transmission. Therefore, it has become the mainstream packaging technology for the next generation of chips.

Due to the superior characteristics of flip-chip ball grid array packages, the flip-chip ball grid array packages are mostly used in high-integration multi-chip packages to meet the needs of miniaturization and high-speed computing. However, due to the high-frequency computing characteristics of this type of package, the heat generated during operation will be higher than that of general packages. Therefore, whether the heat dissipation effect is good or not has become an important key affecting the quality and yield of this type of package.

As shown in FIG. 1, in a manufacturing method of a conventional heat dissipation type semiconductor package 1, a semiconductor chip 11 is firstly disposed on a packaging substrate 10 via an active surface 11a of the semiconductor chip 11 by using flip-chip bonding (that is, via conductive bumps 110 and an underfill 111), and a gold layer (not shown) is formed on an inactive surface 11b of the semiconductor chip 11, and then a heat sink 13 and its top sheet 130 are bonded onto the gold layer by reflowing a thermal interface material (TIM) layer 12 (which includes a solder layer and a flux), and a supporting leg 131 of the heat sink 13 is mounted on the packaging substrate 10 via an adhesive layer 14. Next, a packaging molding operation is performed so that the semiconductor chip 11 and the heat sink 13 are covered with an encapsulation colloid (not shown), and the top sheet 130 of the heat sink 13 is exposed from the encapsulation colloid and is in direct contact with the atmosphere. In addition, a plurality of conductive elements 15 can be disposed on the packaging substrate 10, and the packaging substrate 10 can be subsequently connected to an electronic device (not shown) such as a circuit board via the plurality of conductive elements 15.

During operation, since the heat sink 13 is directly adhered onto the inactive surface 11b of the semiconductor chip 11, the heat generated from the semiconductor chip 11 does not need to be transferred via the encapsulation colloid with poor thermal conductivity. A direct heat dissipation path can be formed from the inactive surface 11b of the semiconductor chip 11 to the outside via the TIM layer 12 and the heat sink 13, thereby achieving better heat dissipation effect than other packages.

However, in the conventional semiconductor package 1, when the heat sink 13 is disposed on the packaging substrate 10, the heat sink 13 is adhered onto the packaging substrate 10 via the supporting leg 131 surrounding the top sheet 130. And the top sheet 130 and the supporting leg 131 are made of integrally formed materials. Therefore, when the semiconductor package 1 undergoes subsequent high-temperature processes, due to the coefficient of thermal expansion (CTE) of the heat sink 13 and the CTE of the semiconductor chip 11 are very different, the thermal deformation of the top sheet 130 of the heat sink 13 will be slightly greater than that of the semiconductor chip 11, and the stress on the semiconductor package 1 is concentrated at the corners. At this time, since the periphery of the top sheet 130 is constrained by the supporting leg 131, the thermal strain of the top sheet 130 is difficult to be released and will cause deformation as shown in FIG. 1, thereby causing delamination between the top sheet 130 and the semiconductor chip 11 or the TIM layer 12 and reducing the heat dissipation performance; and delamination may even occurred between the supporting leg 131 of the heat sink 13 and the packaging substrate 10, causing the heat sink 13 to fall off when it is being shaken.

Therefore, how to overcome the problems of the above-mentioned prior art has become an urgent problem to be solved at present.

### SUMMARY

In view of the aforementioned shortcomings of the prior art, the present disclosure provides a heat dissipation structure, which comprises: a heat sink defined with a central area, a plurality of edge areas located at sides of an outer periphery of the central area, and a plurality of corner areas located at corners of the outer periphery of the central area; and a supporting member disposed on the edge areas and the corner areas of the heat sink, wherein the supporting member has at least one groove at the corner area.

The present disclosure also provides an electronic package, which comprises: a carrying structure; an electronic element disposed on the carrying structure; and a heat dissipation structure disposed on the carrying structure and covering the electronic element, and the heat dissipation structure comprising: a heat sink defined with a central area, a plurality of edge areas located at sides of an outer periphery of the central area, and a plurality of corner areas located at corners of the outer periphery of the central area, wherein the electronic element is located in a region corresponding to the central area; and a supporting member disposed on the edge areas and the corner areas of the heat sink, wherein the supporting member has at least one groove at the corner area.

In the aforementioned electronic package and heat dissipation structure, the groove extends from one end of the supporting member connected to the heat sink to another end of the supporting member.

In the aforementioned electronic package and heat dissipation structure, the groove is located at an inner side of the supporting member.

In the aforementioned electronic package and heat dissipation structure, the groove opens inwardly and is in communication with a space of the central area.

In the aforementioned electronic package and heat dissipation structure, the supporting member continuously connects at outer peripheries of the edge areas and the corner areas without being interrupted by the groove.

In the aforementioned electronic package and heat dissipation structure, the supporting member is distributed within each of the edge areas and each of the corner areas, and the supporting member has the groove at each of the corner areas.

In the aforementioned electronic package and heat dissipation structure, the supporting member and the heat sink are integrally formed or non-integrally formed.

It can be seen from the above that in the electronic package and the heat dissipation structure thereof according to the present disclosure, the supporting member of the heat dissipation structure is disposed around the outer periphery of the central area, and the supporting member is provided with grooves at the corner areas. Accordingly, the grooves can interrupt the stress of the supporting member at the corner areas to avoid the stress from concentrating at the corner areas, and the rest of the supporting member can be well connected and fixed between the heat dissipation structure and the carrying structure, so as to suppress warpage of the entire electronic package and prevent delamination.

### BRIEF DESCRIPTION OF THE DRAWINGS

FIG. 1 is a schematic cross-sectional view showing a conventional heat dissipation type semiconductor package.

FIG. 2A to FIG. 2F are schematic cross-sectional views illustrating a method of manufacturing an electronic package according to the present disclosure.

FIG. 3A is a schematic perspective view showing a heat dissipation structure according to an embodiment of the present disclosure.

FIG. 3B is a schematic planar view showing the heat dissipation structure according to the embodiment of the present disclosure.

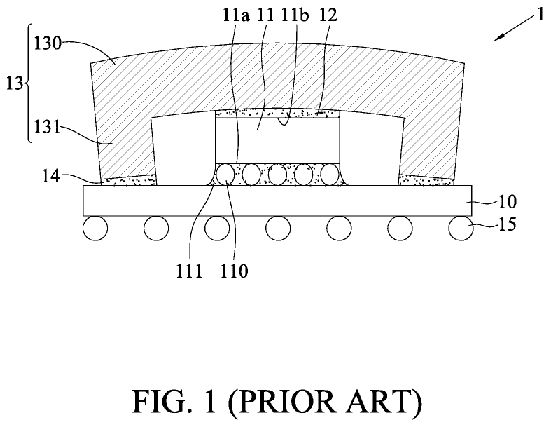

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “under,” “one,” “a,” “first,” “second,” and the like are merely used for clear explanation rather than limiting the practicable scope of the present disclosure, and thus, alterations or adjustments of the relative relationships thereof without essentially altering the technical contents should still be considered in the practicable scope of the present disclosure.

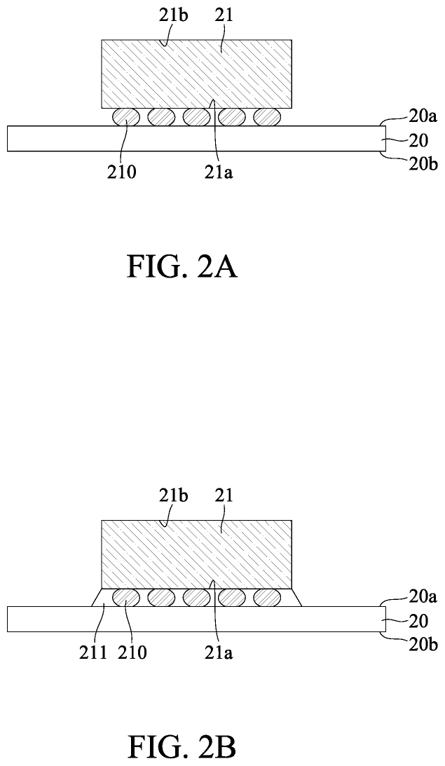

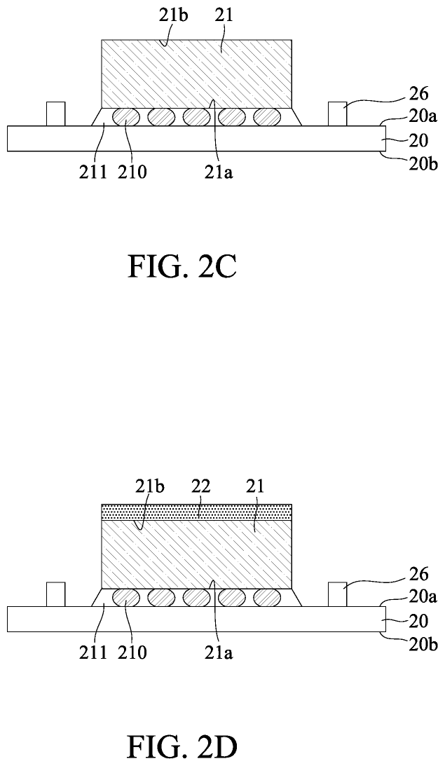

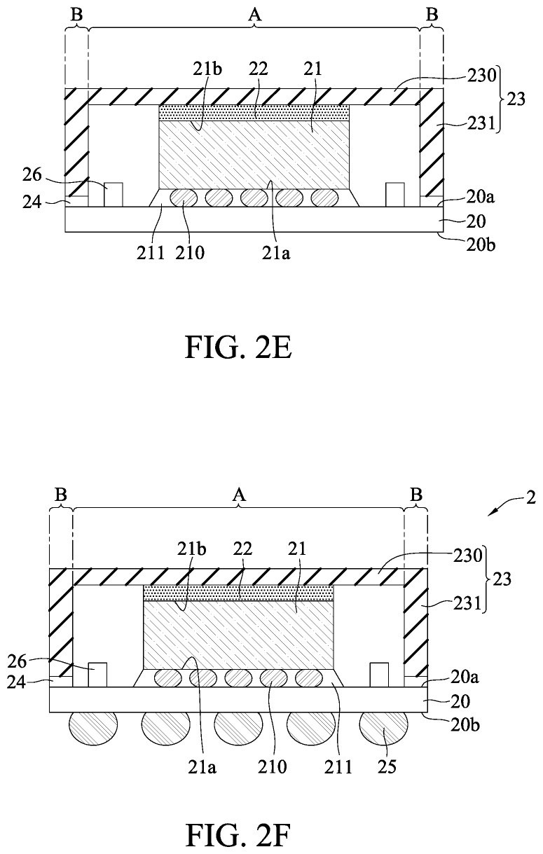

FIG. 2A to FIG. 2F are schematic cross-sectional views illustrating a method of manufacturing an electronic package 2 according to the present disclosure.

As shown in FIG. 2A, a carrying structure 20 is provided and has a first side 20a and a second side 20b opposing the first side 20a, and at least one electronic element 21 is disposed on the first side 20a of the carrying structure 20.

The carrying structure 20 can be a packaging substrate with a core layer and a circuit portion, or a coreless circuit structure.

In an embodiment, the carrying structure 20 comprises at least a dielectric layer and a redistribution layer (RDL) composed of a circuit layer and bonded with the dielectric layer. For instance, the first side 20a of the carrying structure 20 is used as a chip mounting side for carrying the electronic element 21, and the second side 20b of the carrying structure 20 is used as a ball placing side.

It can be understood that the carrying structure 20 can also be other carrying units for carrying chips, such as a lead frame, a silicon interposer, or other boards with metal routings, but not limited to the above.

The electronic element 21 is an active element, a passive element, or a combination of the active element and the passive element, wherein the active element is such as a semiconductor chip, and the passive element is such as a resistor, a capacitor, or an inductor.

In an embodiment, the electronic element 21 is a semiconductor chip and has an active surface 21a and an inactive surface 21b opposing the active surface 21a, and a plurality of electrode pads (not shown) are disposed on the active surface 21a, such that the plurality of electrode pads are bonded with and electrically connected to the circuit layer of the carrying structure 20 in a flip-chip manner via a plurality of conductive bumps 210 made of solder material.

In other embodiments, the electronic element 21 can also be electrically connected to the circuit layer of the carrying structure 20 via a plurality of bonding wires in a wire bonding manner; alternatively, the electronic element 21 can be directly in contact with the circuit layer of the carrying structure 20.

It can be understood that there are various ways for the electronic element 21 to be electrically connected to the carrying structure 20, and the required type and quantity of the electronic element 21 that can be disposed on the carrying structure 20 are not limited to the above.

As shown in FIG. 2B, an encapsulation layer such as an underfill 211 is filled and formed between the first side 20a of the carrying structure 20 and the active surface 21a of the electronic element 21, so as to cover the plurality of conductive bumps 210.

As shown in FIG. 2C, at least one passive element 26 is disposed on the carrying structure 20 and is electrically connected to the circuit layer of the carrying structure 20.

As shown in FIG. 2D, a thermal conductive layer 22 is formed on the inactive surface 21b of the electronic element 21.

In an embodiment, the thermal conductive layer 22 is used as a thermal interface material (TIM). For instance, the thermal conductive layer 22 can be made of solder material with a high thermal conductivity.

As shown in FIG. 2E, a heat dissipation structure 23 is disposed on the first side 20a of the carrying structure 20 and the thermal conductive layer 22 to cover the electronic element 21. The heat dissipation structure 23 has a heat sink 230 that is in contact with and bonded to the thermal conductive layer 22 and a plurality of supporting members 231 downwardly extending from the heat sink 230 and bonded to the carrying structure 20. For instance, the heat sink 230 is in the form of a sheet and can laminate the thermal conductive layer 22, such that the thermal conductive layer 22 is located between the heat sink 230 and the electronic element 21.

In addition, the supporting member 231 is bonded onto the carrying structure 20 via an adhesive layer 24. For instance, the adhesive layer 24 is firstly formed on the first side 20a of the carrying structure 20 by dispensing, such that the adhesive layer 24 is located at the periphery of the passive element 26, and then the supporting member 231 is bonded on the adhesive layer 24 to have the heat dissipation structure 23 fixed on the carrying structure 20.

Afterward, as shown in FIG. 2F, an encapsulation colloid (not shown) can also be formed on the first side 20a of the carrying structure 20 to cover the electronic element 21, and a plurality of conductive elements 25 such as metal pillars (e.g., copper pillars), metal bumps covering insulating blocks, solder balls, solder balls with copper core balls, or other conductive structures are disposed on the second side 20b of the carrying structure 20, thereby obtaining the electronic package 2 of the present disclosure. The electronic package 2 can be subsequently connected to an electronic device (not shown) such as a circuit board via the plurality of conductive elements 25.

When the electronic package 2 is in operation, the heat generated from the electronic element 21 can be transferred to the heat dissipation structure 23 through the inactive surface 21b and the thermal conductive layer 22, so as to dissipate the heat outside the electronic package 2.

As following, the heat dissipation structure 23 of the aforementioned electronic package 2 of the present disclosure will be described in more details.

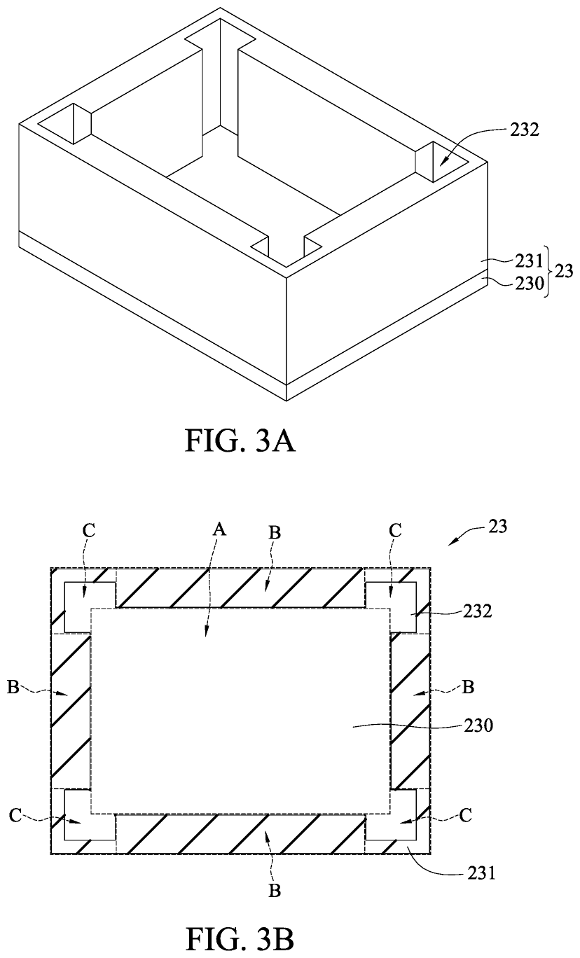

FIG. 3A and FIG. 3B show the heat dissipation structure 23 according to an embodiment of the present disclosure. As shown in FIG. 3B, the heat sink 230 of the heat dissipation structure 23 is defined with a central area A, a plurality of edge areas B located at sides of the outer periphery of the central area A, and a plurality of corner areas C located at corners of the outer periphery of the central area A. For instance, in an embodiment, the heat sink 230 is rectangular and defined with one central area A, four edge areas B and four corner areas C.

In an embodiment, the central area A corresponds to the region where components such as the electronic element 21 and the passive element 26 are disposed (as shown in FIG. 2E and FIG. 2F). In addition, as shown in FIG. 3A and FIG. 3B, the supporting member 231 is disposed around the outer periphery of the central area A and within the edge areas B and the corner areas C, and the supporting member 231 has a groove 232 at the corner area C. In other words, the supporting member 231 is grooved at the corner area C to hollow out part of the supporting member 231 to form the groove 232, and the heat dissipation structure 23 is fixed on the carrying structure 20 by portions of the supporting member 231 distributed in the edge areas B and the corner areas C that are not hollowed out.

As such, the stress of the heat dissipation structure 23 can be interrupted by the grooves 232 and not be concentrated at the corner areas C, thereby preventing the entire structure from warping and delamination. In addition, the supporting member 231 that is disposed around the outer periphery of the central area A can be well connected and fixed between the heat sink 230 and the carrying structure 20. Therefore, the stability of the entire structure can be further improved, and bending deformation can be avoided.

The material of the supporting member 231 can be the same with the material of the heat sink 230, such as a heat dissipation wall or a heat dissipation column made of hard material (metal). As such, the heat dissipation effect of the entire heat dissipation structure 23 can be improved. When the material of the supporting member 231 is the same with the material of the heat sink 230, the heat sink 230 and the supporting member 231 can be integrally formed, but may also be non-integrally formed. Furthermore, it can be understood that the supporting member 231 can also be other components capable of supporting the heat sink 230 and is not limited to the above.

In an embodiment, the groove 232 extends from one end of the supporting member 231 connected to the heat sink 230 to the other end of the supporting member 231 connected to the carrying structure 20, so that the height of the groove 232 is the same with the height of the supporting member 231.

Moreover, the groove 232 is located at the inner side of the heat dissipation structure 23 and opens inwardly, and thus is in communication with a space of the central area A. At this time, wall surfaces of the supporting member 231 distributed in two adjacent edge areas B are cut and separated by the groove 232 at the inner side. Accordingly, the groove 232 of the supporting member 231 can effectively avoid the stress from concentrating at the corner area C.

Additionally, the groove 232 is located at the inner side of the supporting member 231 and does not penetrate laterally to the outer side of the supporting member 231, such that the supporting member 231 is continuously disposed around the outer periphery of the central area A without being interrupted by the groove 232. Accordingly, while the groove 232 of the supporting member 231 can effectively avoid the stress from concentrating at the corner area C, the rest of the supporting member 231 can also be well connected and fixed between the heat sink 230 and the carrying structure 20 to further improve the stability of the entire structure. In an embodiment, wall surfaces of the supporting member 231 at the corner area C that is hollowed out by the groove 232 are presented for example in L-shape, the L-shaped wall surfaces of the supporting member 231 at the corner area C are located at the outer side of the groove 232 with the same thickness, and the L-shaped wall surfaces of the supporting member 231 at the corner area C can connect wall surfaces of the supporting member 231 distributed in two adjacent edge areas B, but the present disclosure is not limited to the above.

Furthermore, in an embodiment, the supporting member 231 is distributed within each of the edge areas B and each of the corner areas C. It can be understood that the supporting member 231 only needs to be sufficient to connect and fix the heat sink 230 and the carrying structure 20, and the supporting member 231 may not be provided within each of the edge areas B and each of the corner areas C.

In addition, in an embodiment, the groove 232 is disposed within every corner area C. It can be understood that as long as it is sufficient to avoid the stress from excessively concentrating in the corner areas C, the groove 232 may not be provided at each of the corner areas C. In other embodiments, the grooves 232 can only be provided in two opposite corner areas C on the diagonal, or different grooves 232 can be provided according to each of the corner areas C. The dimensions of the aforementioned grooves 232 may be the same or different from each other.

Moreover, in other embodiments, the supporting member 231 can be grooved inside the edge areas B to further interrupt the stress inside the edge areas B.

To sum up, in the electronic package and the heat dissipation structure thereof according to the present disclosure, the supporting member of the heat dissipation structure is disposed around the outer periphery of the central area of the heat sink, and the supporting member is provided with grooves at the corner areas. Accordingly, the grooves can interrupt the stress of the supporting member at the corner areas to avoid the stress from concentrating at the corner areas, and the rest of the supporting member can well connect and fix the heat dissipation structure and the carrying structure, so as to suppress warpage of the entire electronic package and prevent delamination.

In addition, the grooves of the present disclosure are located at the inner side and open inwardly, and are in communication with a space of the central area. Accordingly, the grooves of the supporting member can effectively avoid the stress from concentrating at the corner areas.

Furthermore, the grooves of the present disclosure are located at the inner side of the supporting member without penetrating to the outer side of the supporting member, so that the supporting member continuously connects at the outer peripheries of the edge areas and the corner areas without being interrupted by the grooves. Therefore, the supporting member can avoid the stress from concentrating at the corner areas while being well connected and fixed between the heat sink and the carrying structure, so as to further improve the stability of the entire structure.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A heat dissipation structure, comprising:
a heat sink defined with a central area, a plurality of edge areas located at sides of an outer periphery of the central area, and a plurality of corner areas located at corners of the outer periphery of the central area; and
a supporting member disposed on the edge areas and the corner areas of the heat sink, wherein the supporting member has at least one groove at the corner area.

2. The heat dissipation structure of claim 1, wherein the groove extends from one end of the supporting member connected to the heat sink to another end of the supporting member.

3. The heat dissipation structure of claim 1, wherein the groove is located at an inner side of the supporting member.

4. The heat dissipation structure of claim 1, wherein the groove opens inwardly and is in communication with a space of the central area.

5. The heat dissipation structure of claim 1, wherein the supporting member continuously connects at outer peripheries of the edge areas and the corner areas without being interrupted by the groove.

6. The heat dissipation structure of claim 1, wherein the supporting member is distributed within each of the edge areas and each of the corner areas, and the supporting member has the groove at each of the corner areas.

7. The heat dissipation structure of claim 1, wherein the supporting member and the heat sink are integrally formed or non-integrally formed.

8. An electronic package, comprising:
a carrying structure;
an electronic element disposed on the carrying structure; and
a heat dissipation structure disposed on the carrying structure and covering the electronic element, and the heat dissipation structure comprising:
a heat sink defined with a central area, a plurality of edge areas located at sides of an outer periphery of the central area, and a plurality of corner areas located at corners of the outer periphery of the central area, wherein the electronic element is located in a region corresponding to the central area; and
a supporting member disposed on the edge areas and the corner areas of the heat sink, wherein the supporting member has at least one groove at the corner area.

9. The electronic package of claim 8, wherein the groove extends from one end of the supporting member connected to the heat sink to another end of the supporting member.

10. The electronic package of claim 8, wherein the groove is located at an inner side of the supporting member.

11. The electronic package of claim 8, wherein the groove opens inwardly and is in communication with a space of the central area.

12. The electronic package of claim 8, wherein the supporting member continuously connects at outer peripheries of the edge areas and the corner areas without being interrupted by the groove.

13. The electronic package of claim 8, wherein the supporting member is distributed within each of the edge areas and each of the corner areas, and the supporting member has the groove at each of the corner areas.

14. The electronic package of claim 8, wherein the supporting member and the heat sink are integrally formed or non-integrally formed.
